(19) United States
(12) Patent Application Publication
(10) Pub. No.: US 2024/0429050 A1
(43) Pub. Date: Dec. 26, 2024

(54) PRODUCTION METHOD FOR SEMICONDUCTOR DEVICE

(71) Applicant: SUMITOMO ELECTRIC INDUSTRIES, LTD., Osaka (JP)

(72) Inventor: Isao MAKABE, Osaka (JP)

(21) Appl. No.: 18/745,100

(22) Filed: Jun. 17, 2024

(30) Foreign Application Priority Data
Jun. 22, 2023 (JP) 2023-102364

(51) Int. Cl. H01L 21/02; H01L 21/033; H01L 29/66

(52) U.S. Cl. CPC H01L 21/0254; H01L 21/0262; H01L 21/0332; H01L 29/66462

(57) ABSTRACT

A production method for a semiconductor device includes forming a first nitride semiconductor layer containing gallium, on a substrate; forming a mask layer b on the first nitride semiconductor layer; forming an opening in the mask layer, a part of the first nitride semiconductor layer being exposed from the opening; performing a reduction treatment of a first surface of the first nitride semiconductor layer in a chamber using a first gas mixture containing hydrogen and ammonia, the first surface being exposed from the opening; forming a second nitride semiconductor layer of a first conductive type on the first surface through metal organic chemical vapor deposition in the chamber using a second gas mixture containing hydrogen, nitrogen, ammonia, and a source material of a Group III element; and forming an electrode on the second nitride semiconductor layer.

### CROSS-REFERENCE TO RELATED APPLICATIONS

This application is based on and claims priority to Japanese Patent Application No. 2023-102364, filed on Jun. 22, 2023, the entire contents of which are incorporated herein by reference.

### TECHNICAL FIELD

The present disclosure relates to production methods for semiconductor devices.

### BACKGROUND

In order to reduce contact resistance in semiconductor devices using nitride semiconductors, a structure in which a nitride semiconductor layer containing impurities at a high concentration is re-grown, is proposed. See, for example, PCT Japanese Translation Patent Publication No. 2007-538402 and Japanese Patent Application Publication No. 2019-033155.

### SUMMARY

A production method for a semiconductor device of the present disclosure includes: forming a first nitride semiconductor layer containing gallium, on a substrate; forming a mask layer on the first nitride semiconductor layer; forming an opening in the mask layer, a part of the first nitride semiconductor layer being exposed from the opening; performing a reduction treatment of a first surface of the first nitride semiconductor layer in a chamber using a first gas mixture containing hydrogen and ammonia, the first surface being exposed from the opening; forming a second nitride semiconductor layer of a first conductive type on the first surface through metal organic chemical vapor deposition in the chamber using a second gas mixture containing hydrogen, nitrogen, ammonia, and a source b material of a Group III element; and forming an electrode on the second nitride semiconductor layer.

### BRIEF DESCRIPTION OF THE DRAWINGS

FIG. 1 is a cross-sectional view illustrating a production method for a semiconductor device according to a first embodiment (part 1);

FIG. 2 is a cross-sectional view illustrating the production method for the semiconductor device according to the first embodiment (part 2);

FIG. 3 is a cross-sectional view illustrating the production method for the semiconductor device according to the first embodiment (part 3);

FIG. 4 is a cross-sectional view illustrating the production method for the semiconductor device according to the first embodiment (part 4);

FIG. 5 is a cross-sectional view illustrating the production method for the semiconductor device according to the first embodiment (part 5);

FIG. 6 is a cross-sectional view illustrating the production method for the semiconductor device according to the first embodiment (part 6);

FIG. 7 is a cross-sectional view illustrating the production method for the semiconductor device according to the first embodiment (part 7);

FIG. 8 is a cross-sectional view illustrating the production method for the semiconductor device according to the first embodiment (part 8);

FIG. 9 is a cross-sectional view illustrating a production method for a semiconductor device according to a second embodiment (part 1);

FIG. 10 is a cross-sectional view illustrating the production method for the semiconductor device according to the second embodiment (part 2);

FIG. 11 is a cross-sectional view illustrating the production method for the semiconductor device according to the second embodiment (part 3);

FIG. 12 is a cross-sectional view illustrating the production method for the semiconductor device according to the second embodiment (part 4);

FIG. 13 is a cross-sectional view illustrating a production method for a semiconductor device according to a third embodiment (part 1);

FIG. 14 is a cross-sectional view illustrating the production method for the semiconductor device according to the third embodiment (part 2);

FIG. 15 is a cross-sectional view illustrating the production method for the semiconductor device according to the third embodiment (part 3);

FIG. 16 is a cross-sectional view illustrating the production method for the semiconductor device according to the third embodiment (part 4);

FIG. 17 is a cross-sectional view illustrating the production method for the semiconductor device according to the third embodiment (part 5);

FIG. 18 is a cross-sectional view illustrating the production method for the semiconductor device according to the third embodiment (part 6);

FIG. 19 is a cross-sectional view illustrating the production method for the semiconductor device according to the third embodiment (part 7);

FIG. 20 is a cross-sectional view illustrating the production method for the semiconductor device according to the third embodiment (part 8);

FIG. 21 is a cross-sectional view illustrating the production method for the semiconductor device according to the third embodiment (part 9); and

FIG. 22 is a graph illustrating an example of a relationship between a second nitride semiconductor layer and a percentage of a flow rate of nitrogen relative to a total flow rate of hydrogen and nitrogen in a second gas mixture.

### DETAILED DESCRIPTION

In recent years, further reduction in the contact resistance is desired to further increase a drive speed. However, it is challenging to further reduce the contact resistance by existing production methods.

The present disclosure provides a production method for a semiconductor device that is capable of further reducing the contact resistance.

According to the present disclosure, it is possible to further reduce the contact resistance.

### Description of Embodiments of the Present Disclosure

First, embodiments of the present disclosure will be described below.

[1] A production method for a semiconductor device according to one aspect of the present disclosure includes: forming a first nitride semiconductor layer containing gallium, on a substrate; forming a mask layer on the first nitride semiconductor layer; forming an opening in the mask layer, a part of the first nitride semiconductor layer being exposed from the opening; performing a reduction treatment of a first surface of the first nitride semiconductor layer in a chamber using a first gas mixture containing hydrogen and ammonia, the first surface being exposed from the opening; forming a b second nitride semiconductor layer of a first conductive type on the first surface through metal organic chemical vapor deposition in the chamber using a second gas mixture containing hydrogen, nitrogen, ammonia, and a source material of a Group III element; and forming an electrode on the second nitride semiconductor layer.

The reduction treatment is performed in the chamber in which the second nitride semiconductor layer is to be formed, and the second nitride semiconductor layer is formed in this chamber. Therefore, even if a native oxide film is formed on the first surface of the first nitride semiconductor layer before the reduction treatment, the second nitride semiconductor layer is formed in a state in which the native oxide film is removed. Therefore, the contact resistance between the electrode and the first nitride semiconductor layer can be reduced.

[2] In [1], the mask layer may be a silicon nitride layer. In this case, the mask layer may be used as a gate insulating film.

[3] In [1] or [2], the second nitride semiconductor layer may be an n-type gallium nitride layer. In this case, resistance of the n-type gallium nitride layer is low, and thus the contact resistance between the electrode and the first nitride semiconductor layer is readily reduced.

[4] In any one of [1] to [3], the first gas mixture may contain nitrogen. In this case, nitrogen can suppress etching of the first nitride semiconductor layer caused by hydrogen.

[5] In any one of [1] to [4], the first surface may be a surface having nitrogen polarity. In this case, resistance of a current flow path in the first nitride b semiconductor layer is readily reduced while suppressing the contact resistance.

[6] In [5], the formation of the first nitride semiconductor layer may include forming a barrier layer and forming a channel layer on the barrier layer. In this case, it is possible to form a high electron mobility transistor in which the contact resistance between the electrode and the first nitride semiconductor layer is low.

[7] In [6], the production method for the semiconductor device may further include forming a recess at a part of the channel layer between the formation of the opening and the reduction treatment, the part being exposed from the opening, and the first surface may be an inner surface of the recess. In this case, it is possible to reduce the distance between the second nitride semiconductor layer and the channel region of the high electron mobility transistor. Therefore, further reduction in the contact resistance is possible.

[8] In any one of [1] to [7], the second gas mixture may contain triethylgallium as the source material of the Group III element. In this case, the growth rate of the second nitride semiconductor layer is readily lowered, thereby readily suppressing the formation of the second nitride semiconductor layer on the mask layer.

[9] In any one of [1] to [8], a percentage of a flow rate of nitrogen relative to a total flow rate of hydrogen and nitrogen in the second gas mixture may be 30% or more and 95% or less. In this case, sheet resistance of the second nitride semiconductor layer is readily lowered.

### Details of Embodiments of Present Disclosure

Embodiments of the present disclosure will be described below in detail, but the present disclosure is not limited thereto. In the present specification and drawings, components having substantially the same functional configuration are denoted by the same reference numerals, and duplicate description thereof may be omitted.

### First Embodiment

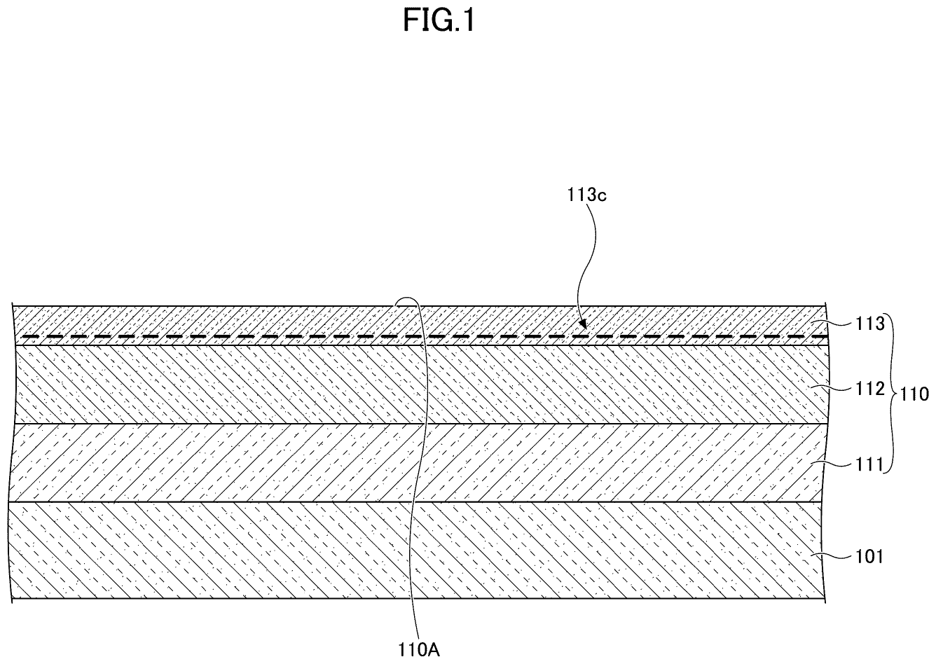

The first embodiment will be described below. The first embodiment relates to a production method for a semiconductor device including a GaN-based high electron mobility transistor (HEMT). FIGS. 1 to 8 are cross-sectional views illustrating the production method for the semiconductor device according to the first embodiment.

In the first embodiment, first, as illustrated in FIG. 1, a nitride semiconductor layer 110 containing gallium (Ga) is formed on a substrate 101, for example, through metal organic chemical vapor deposition (MOCVD). In the formation of the nitride semiconductor layer 110, a buffer layer 111, a barrier layer 112, and a channel layer 113 are formed sequentially. The nitride semiconductor layer 110 is an example of the first nitride semiconductor layer.

The substrate 101 is, for example, a substrate for growth of a gallium nitride (GaN)-based semiconductor. In one example, the substrate 101 is a silicon carbide (SiC) substrate that is semi-insulating. When the substrate 101 is the SiC substrate, the surface of the substrate 101 is a surface having carbon (C) polarity. When the surface of the substrate 101 is the surface having carbon (C) polarity, crystal growth of the buffer layer 111, the barrier layer 112, and the channel layer 113 can be performed with the surface having nitrogen (N) polarity being the growth surface. A sapphire substrate may be used as the substrate for growth of the GaN-based semiconductor. Alternatively, the substrate 101 may not be a substrate for crystal growth, in which case, the buffer layer 111, the barrier layer 112, and the channel layer 113 may be grown on a separately provided substrate, and after removal of this substrate, the buffer layer 111, the barrier layer 112, and the channel layer 113 may be bonded to the substrate 101. In this case, a semi-insulating substrate of various materials may be used as the substrate 101. For example, a sapphire substrate, a silicon (Si) substrate, a SiC substrate, an aluminum nitride (AlN) substrate, a sintered body substrate, or the like can be used.

The buffer layer 111 is, for example, an AlN layer. The thickness of the AlN layer is, for example, 5 nm or greater and 100 nm or smaller. The buffer layer 111 may include: an AlN layer; and a GaN layer on the AlN layer or an aluminum gallium nitride (AlGaN) layer on the AlN layer. The thickness of the GaN layer or the AlGaN layer is, for example, 300 nm or greater and 2,000 nm or smaller.

The barrier layer 112 is, for example, an AlGaN layer. The band gap of the barrier layer 112 is greater than the band gap of the channel layer 113. The thickness of the barrier layer 112 is, for example, 5 nm or greater and 50 nm or smaller. In one example, the thickness of the barrier layer 112 may be 30 nm. When the barrier layer 112 is an AlₓGa₁₋ₓN layer, “x” for Al is, for example, 0.15 or greater and 0.55 or smaller. In one example, “x” for Al may be 0.35. The conductive type of the barrier layer 112 is, for example, an n-type or an b undoped type (i-type). Instead of the AlGaN layer, an indium aluminum nitride (InAlN) layer or an indium aluminum gallium nitride (InAlGaN) layer may be used.

The channel layer 113 is, for example, a GaN layer. The band gap of the channel layer 113 is smaller than the band gap of the barrier layer 112. The thickness of the channel layer 113 is, for example, 5 nm or greater and 30 nm or smaller. In one example, the thickness of the channel layer 113 may be 9 nm. Distortion occurs between the channel layer 113 and the barrier layer 112 due to the difference in lattice constants thereof, and this distortion induces piezoelectric charges at the interface between the channel layer 113 and the barrier layer 112. This generates two-dimensional electron gas (2 DEG) near the interface between the channel layer 113 and the barrier layer 112, and forms a channel region 113c. The conductive type of the channel layer 113 is, for example, an n-type or an undoped type (i-type). The surface of the channel layer 113 forms a surface 110A of the nitride semiconductor layer 110. Also, a spacer layer may be formed between the barrier layer 112 and the channel layer 113. The spacer layer is, for example, an AlN layer. The thickness of the spacer layer is, for example, 0.5 nm or greater and 3.0 nm or smaller. In one example, the thickness of the spacer layer may be 1.0 nm.

On the surface having C polarity of the SiC substrate, crystal growth of the buffer layer 111, the barrier layer 112, and the channel layer 113 is performed with the surface having N polarity being the growth surface. Therefore, of the two main surfaces of the buffer layer 111, the barrier layer 112, or the channel layer 113, the main surface the farthest from the b substrate 101 (upper surface) becomes a surface having N polarity, and the main surface the closest to the substrate 101 (lower surface) becomes a surface having Ga polarity.

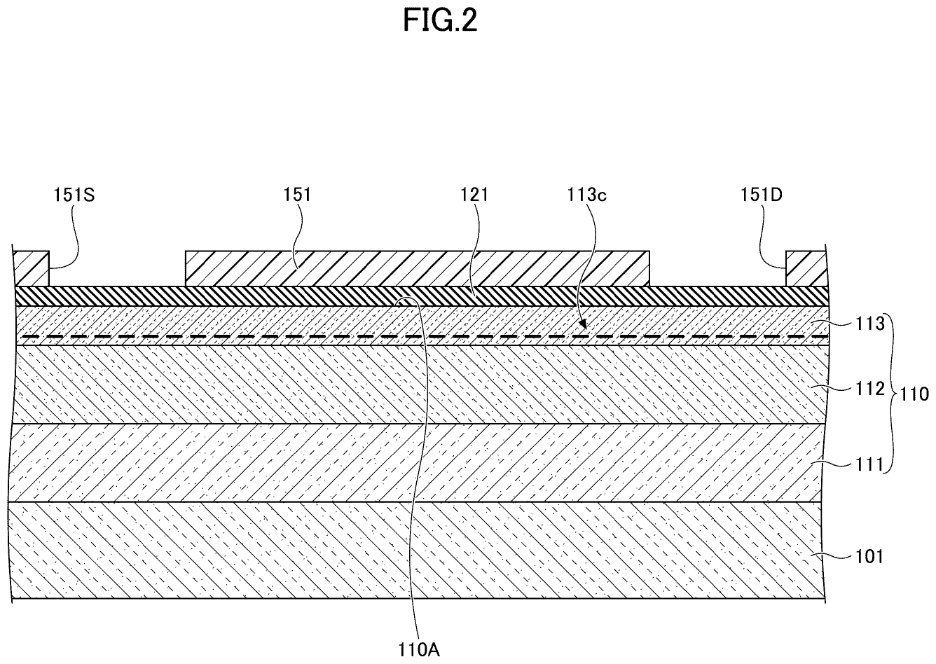

Next, as illustrated in FIG. 2, a silicon nitride (SiN) layer 121 contacting the surface 110A of the nitride semiconductor layer 110 is formed. The SiN layer 121 can be formed, for example, through low-pressure CVD (LPCVD). Next, a resist pattern 151 is formed on the SiN layer 121. The resist pattern 151 has an opening 151S for a source and an opening 151D for a drain. The SiN layer 121 is an example of the mask layer.

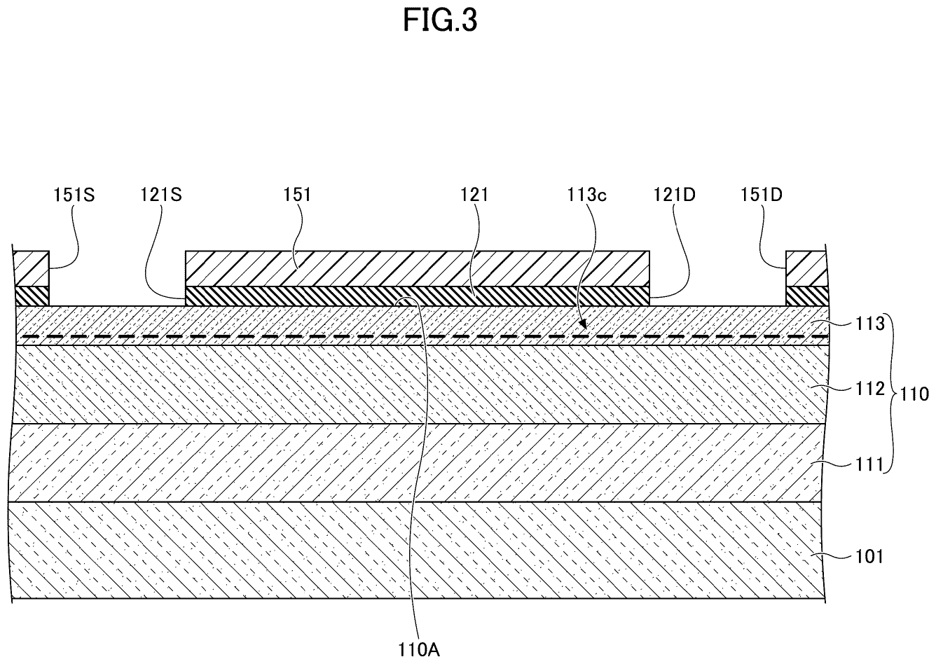

Next, as illustrated in FIG. 3, the SiN layer 121 is etched using the resist pattern 151 as a mask. This etching is, for example, reactive ion etching (RIE) using fluorine-containing gas. As a result, an opening 121S is formed at the SiN layer 121 below the opening 151S, and an opening 121D is formed at the SiN layer 121 below the opening 151D. A part of the nitride semiconductor layer 110 is exposed from the opening 121S, and another part of the nitride semiconductor layer 110 is exposed from the opening 121D.

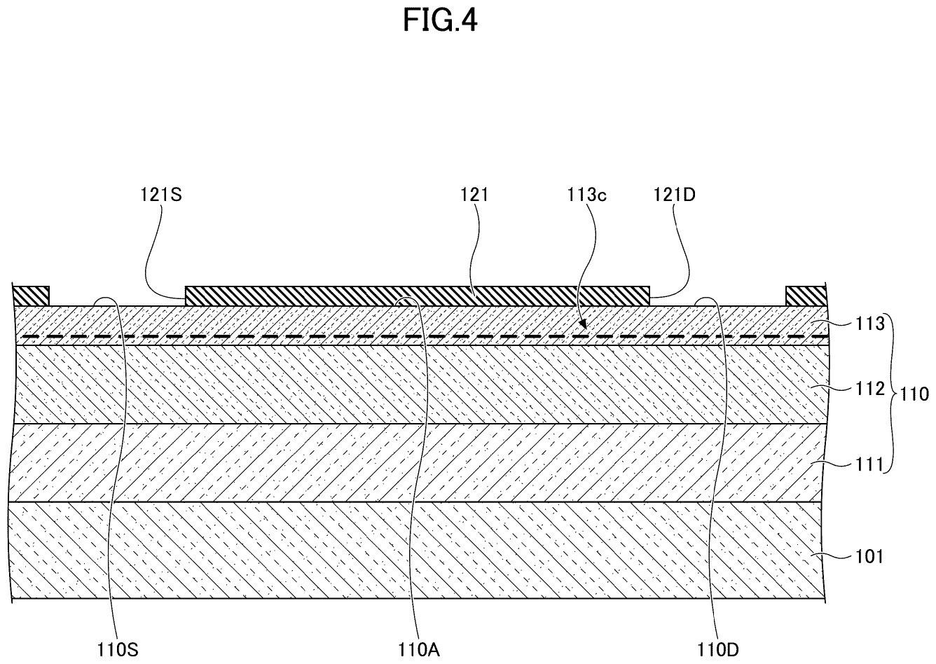

Next, as illustrated in FIG. 4, the resist pattern 151 is removed using a chemical solution. Next, a surface 110S, exposed from the opening 121S of the nitride semiconductor layer 110, and a surface 110D, exposed from the opening 121D of the nitride semiconductor layer 110, are subjected to the reduction treatment in a MOCVD chamber using the first gas mixture containing nitrogen (N₂), hydrogen (H₂), and ammonia (NH₃). In this reduction treatment, for example, the temperature of the substrate 101 is set to be 700° C. or higher and 900° C. or lower, and may be set to be 750° C. or higher and 850° C. or lower. During the period of from the formation of the openings 121S and 121D until the removal of the resist pattern 151, a native oxide film can be formed on the surfaces 110S and 110D. However, the native oxide film is removed with this reduction treatment. For example, the surfaces 110S and 110D are a part of the surface 110A. The surfaces 110S and 110D are an example of the first surface.

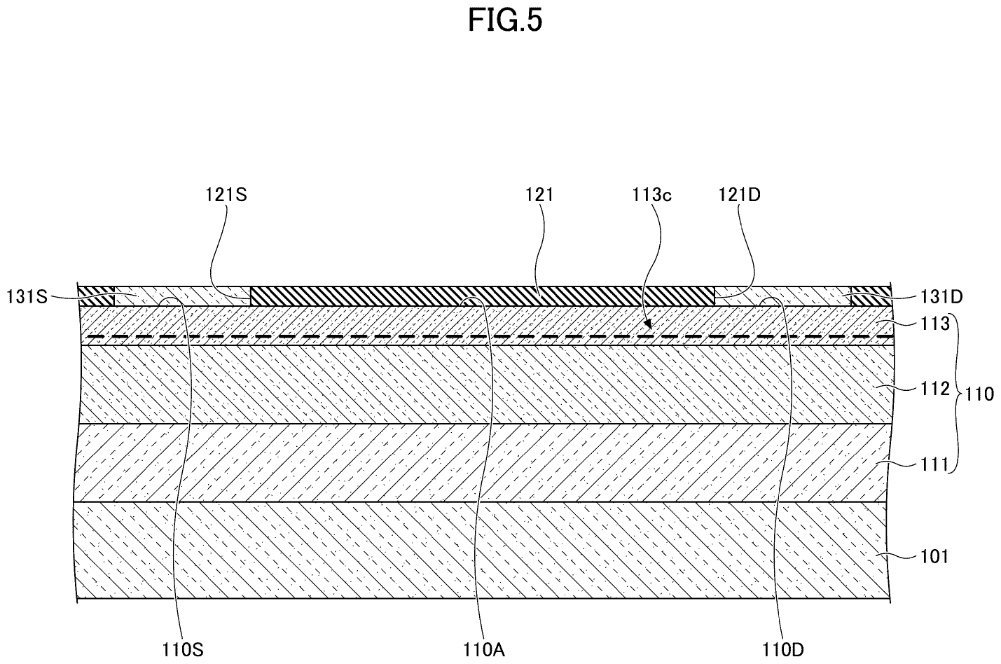

Next, as illustrated in FIG. 5, an n-type GaN layer 131S is formed on the surface 110S, and an n-type GaN layer 131D is formed on the surface 110D. In the formation of the n-type GaN layers 131S and 131D, the film formation is performed using the second gas mixture, containing N₂, H₂, NH₃, and a source material of gallium, in the same MOCVD chamber without exposing the MOCVD chamber to the atmosphere. As the source material of gallium, for example, triethylgallium (TEG) is used. For example, the n-type dopant is silicon (Si) or germanium (Ge), and the concentration of the n-type dopant is 1×10¹⁷ cm⁻³ or higher. In this film formation, for example, the temperature of the substrate 101 is set to be 700° C. or higher and 900° C. or lower, and may be set to be 750° C. or higher and 850° C. or lower. In this film formation, for example, the pressure in the MOCVD chamber is set to be 13.3 kPa (100 Torr) or higher and 101.3 kPa (760 Torr) or lower, and may be set to be 40.0 kPa (300 Torr) or higher and 101.3 kPa (760 Torr) or lower. The n-type GaN layers 131S and 131D are an example of the second nitride semiconductor layer.

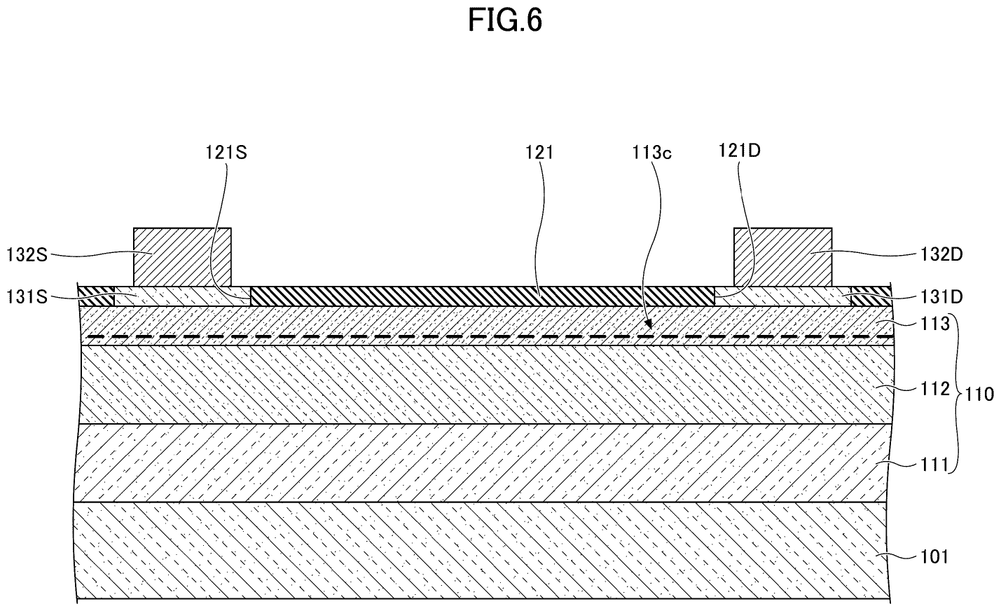

Next, as illustrated in FIG. 6, a source electrode 132S is formed on the n-type GaN layer 131S, and a drain electrode 132D is formed on the n-type GaN layer 131D. In the formation of the source electrode 132S and the drain electrode 132D, first, multiple metal layers forming the source electrode 132S and the drain electrode 132D are vapor deposited, thereby forming a stacked structure. Subsequently, the stacked structure is thermally treated for alloying. In the formation of the stacked structure, for example, a tantalum (Ta) layer, an aluminum (Al) layer, and a Ta layer may be formed sequentially, or a titanium (Ti) layer, an Al layer, and a Ti layer may be formed sequentially. The source electrode 132S and the drain electrode 132D are an example of the electrode.

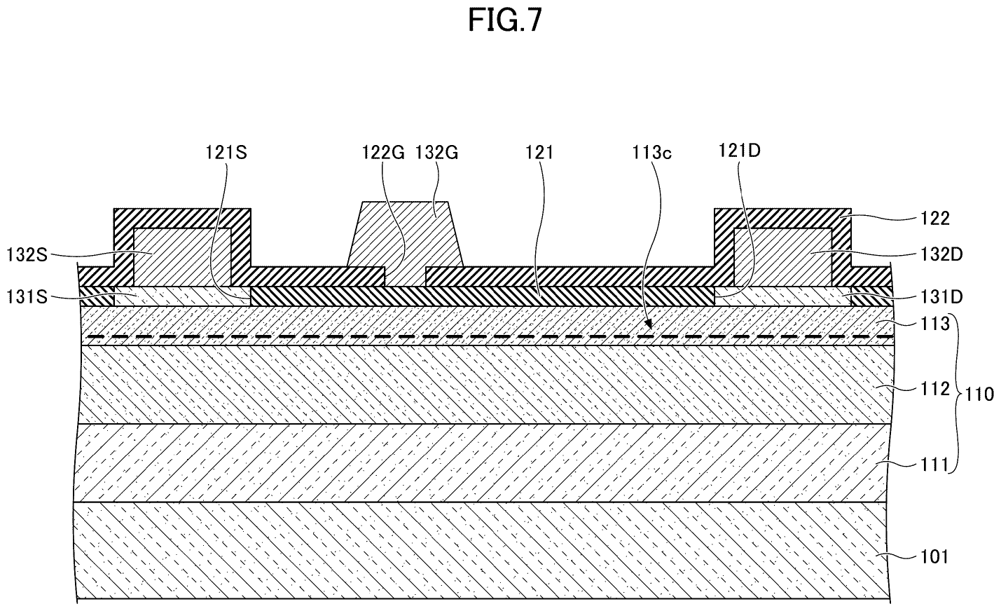

Next, as illustrated in FIG. 7, a SiN layer 122 is formed on the SiN layer 121. The SiN layer 122 covers the n-type GaN layer 131S, the source electrode 132S, the n-type GaN layer 131D, and the drain electrode 132D. Next, an opening 122G is formed at the SiN layer 122 between the source electrode 132S and the drain electrode 132D. A part of the SiN layer 121 is exposed from the opening 122G. Next, a gate electrode 132G contacting the SiN layer 121 through the opening 122G is formed. In the formation of the gate electrode 132G, multiple metal layers forming the gate electrode 132G are vapor deposited, thereby forming a stacked structure. In the formation of the laminated structure, for example, a nickel (Ni) layer, a palladium (Pd) layer, and an Au layer may be formed sequentially.

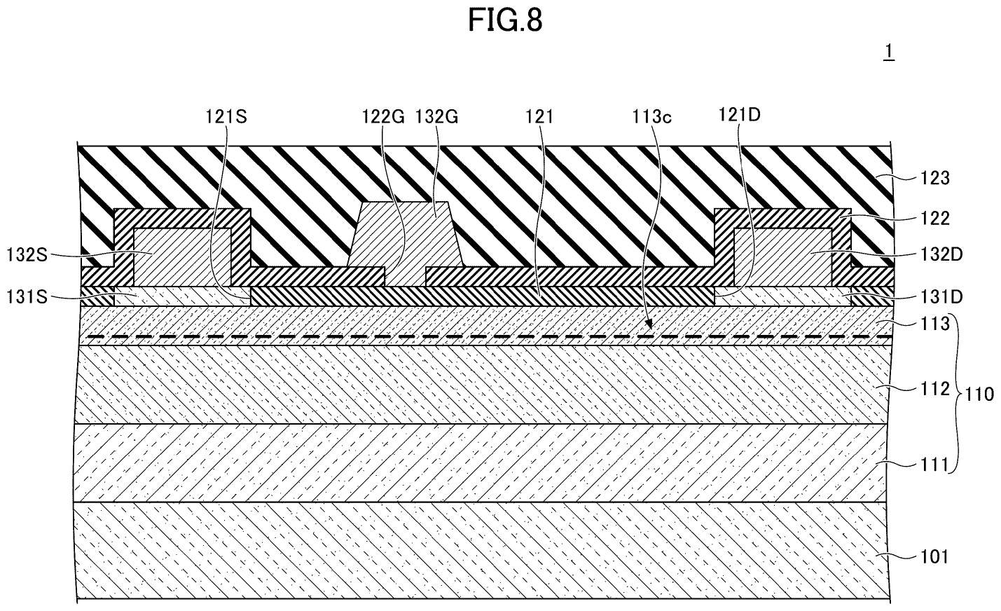

Next, as illustrated in FIG. 8, a SiN layer 123 is formed on the SiN layer 122. The SiN layer 123 covers the gate electrode 132G.

In this manner, a semiconductor device 1 can be produced.

In the first embodiment, the reduction treatment is performed in the MOCVD chamber in which the n-type GaN layers 131S and 131D are to be formed, and the n-type GaN layers 131S and 131D are formed in this MOCVD chamber. Therefore, the n-type GaN layers 131S and 131D are formed in a state in which the native oxide film is removed. Thus, the contact resistance between: the source electrode 132S and the drain electrode 132D; and the nitride semiconductor layer 110 can be reduced. Also, the SiN layer 121 is used as a gate insulating film.

H₂ contained in the first gas mixture contributes to the reduction, NH₃ suppresses desorption of Ga from the nitride semiconductor layer 110, and N₂ suppresses etching of the nitride semiconductor layer 110 caused by H₂.

The NH₃ and the source material of gallium contained in the second gas mixture are used as materials forming the n-type GaN layers 131S and 131D. When H₂ is contained in the second gas mixture, the growth rate of the n-type GaN layer is readily lowered upon forming the n-type GaN layers 131S and 131D. Therefore, the n-type GaN layers 131S and 131D readily contain an n-type dopant at a high concentration. When H₂ is contained in the second gas mixture, the formation of the n-type GaN layer on the SiN layer 121 is readily suppressed. Also, when TEG is used as the source material of gallium, the growth rate of the n-type GaN layer is readily lowered upon forming the n-type GaN layers 131S and 131D, and the n-type GaN layers 131S and 131D readily contain an n-type dopant at a high concentration. For example, the growth rate of the n-type GaN layers 131S and 131D is 0.04 nm/sec or higher and 0.08 nm/sec or lower, and may be 0.05 nm/sec or higher and 0.07 nm/sec or lower.

The nitride semiconductor layers formed between: the nitride semiconductor layer 110; and the source electrode 132S and the drain electrode 132D are the n-type GaN layers 131S and 131D, and thus the contact resistance is readily reduced.

The surface 110A of the nitride semiconductor layer 110 is a surface having N polarity. Thus, even if the amount of Al in the barrier layer 112 is increased, it is possible to avoid an increase in the contact resistance. Therefore, the resistance of the channel region 113c is readily reduced by increasing the concentration of 2 DEG. Especially, the channel layer 113 is formed on the barrier layer 112, and thus the resistance of the channel region 113c is readily reduced.

### Second Embodiment

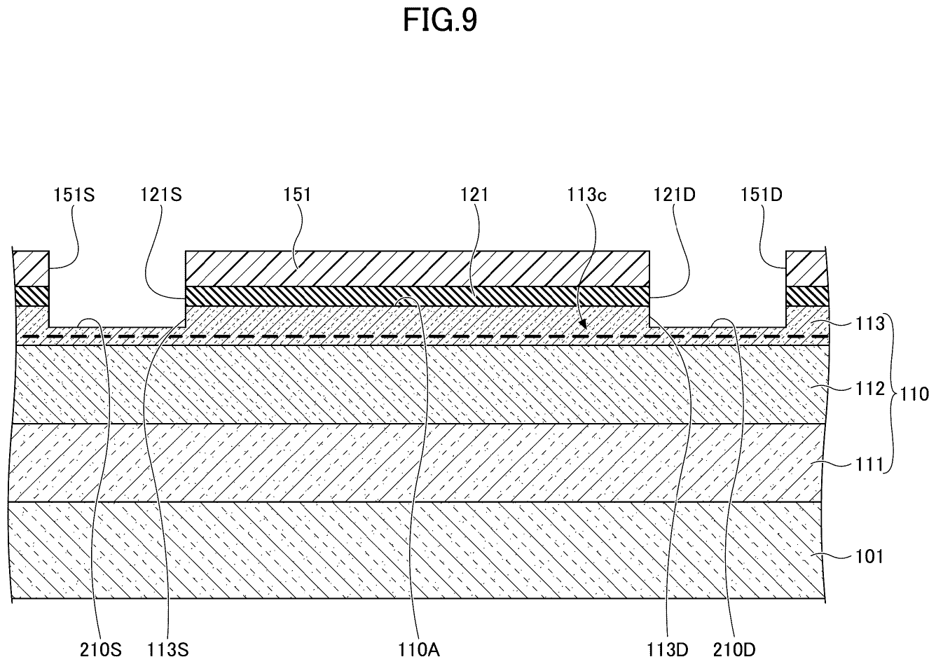

Next, the second embodiment will be described. The second embodiment relates to a production method for a semiconductor device including a GaN-based HEMT. FIGS. 9 to 12 are cross-sectional views illustrating the production method for the semiconductor device according to the second embodiment.

In the second embodiment, first, a process until the formation of the openings 121S and 121D is performed in the same manner as in the first embodiment (see FIG. 3). Next, as illustrated in FIG. 9, by etching the channel layer 113 using the resist pattern 151 as a mask, a recess 113S continuous with the opening 121S and a recess 113D continuous with the opening 121D are formed at the channel layer 113. This etching is, for example, RIE using chlorine-containing gas. For example, the recesses 113S and 113D are formed at a depth that does not reach the channel region 113c. That is, the recesses 113S and 113D are not deeper than the channel region 113c, with the reference being the surface 110A of the nitride semiconductor layer 110.

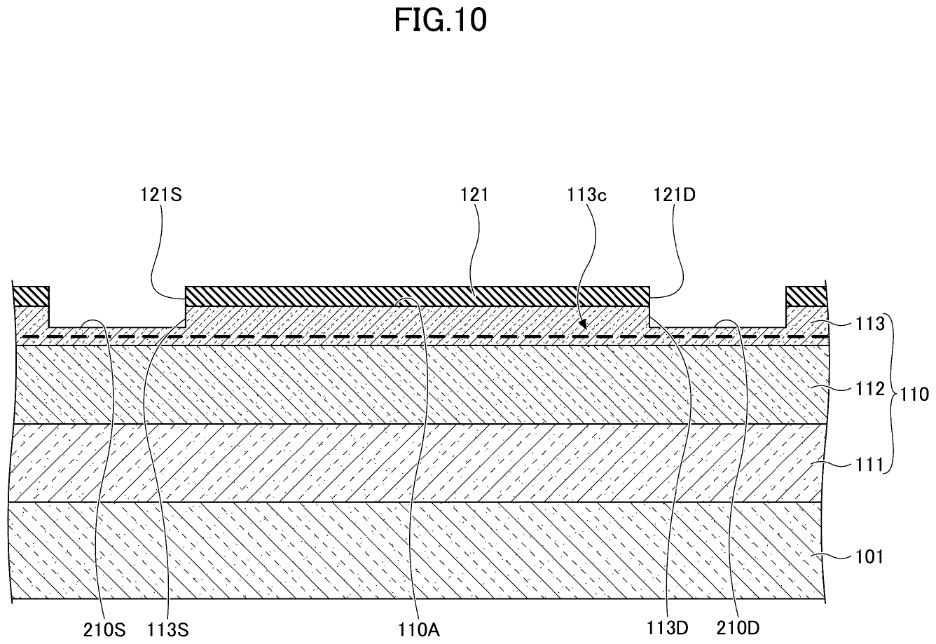

Next, as illustrated in FIG. 10, the resist pattern 151 is removed using a chemical solution. Next, a surface 210S, exposed from the opening 121S of the nitride semiconductor layer 110, and a surface 210D, exposed from the opening 121D of the nitride semiconductor layer 110, are subjected to the reduction treatment in a MOCVD chamber using the first gas mixture containing N₂, H₂, and NH₃. During the period of from the formation of the openings 121S and 121D until the removal of the resist pattern 151, a native oxide film can be formed on the surfaces 210S and 210D. However, the native oxide film is removed with this reduction treatment. For example, the surface 210S is an inner surface (bottom surface and side wall surface) of the recess 113S, and the surface 210D is an inner surface (bottom surface and side wall surface) of the recess 113D. The surfaces 210S and 210D are an example of the first surface.

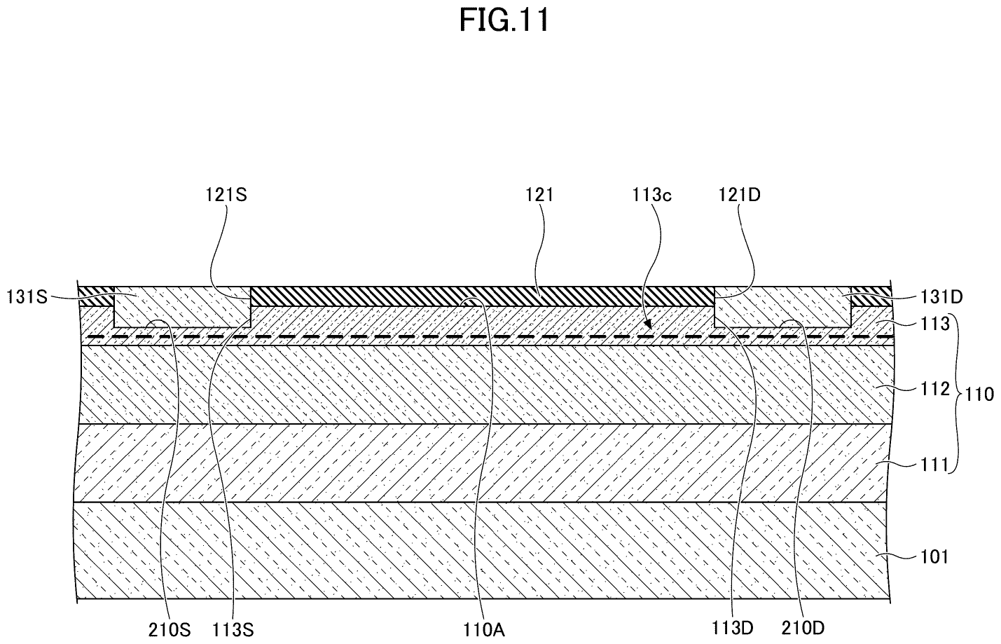

Next, as illustrated in FIG. 11, an n-type GaN layer 131S is formed on the surface 210S, and an n-type GaN layer 131D is formed on the surface 210D. In the formation of the n-type GaN layers 131S and 131D, the film formation is performed using the second gas mixture, containing N₂, H₂, NH₃, and a source material of gallium, in the same MOCVD chamber without exposing the MOCVD chamber to the atmosphere. For example, TEG is used as the source material of gallium.

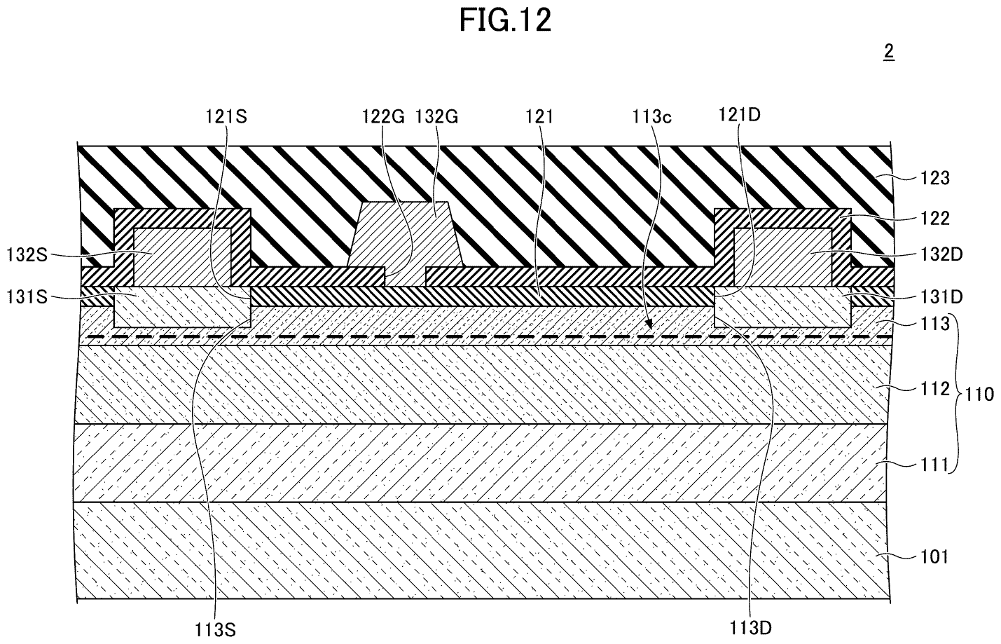

Next, as illustrated in FIG. 12, a process following the formation of the source electrode 132S and the drain electrode 132D is performed in the same manner as in the first embodiment.

In this manner, a semiconductor device 2 can be produced.

The same effects as in the first embodiment can be obtained in the second embodiment. In the second embodiment, the recesses 113S and 113D are formed, and the n-type GaN layer 131S is formed on the surface 210S and the n-type GaN layer 131D is formed on the surface 210D. It is possible to reduce the distance between: the n-type GaN layers 131S and 131D; and the channel region 113c. Therefore, further reduction in the contact resistance is possible.

### Third Embodiment

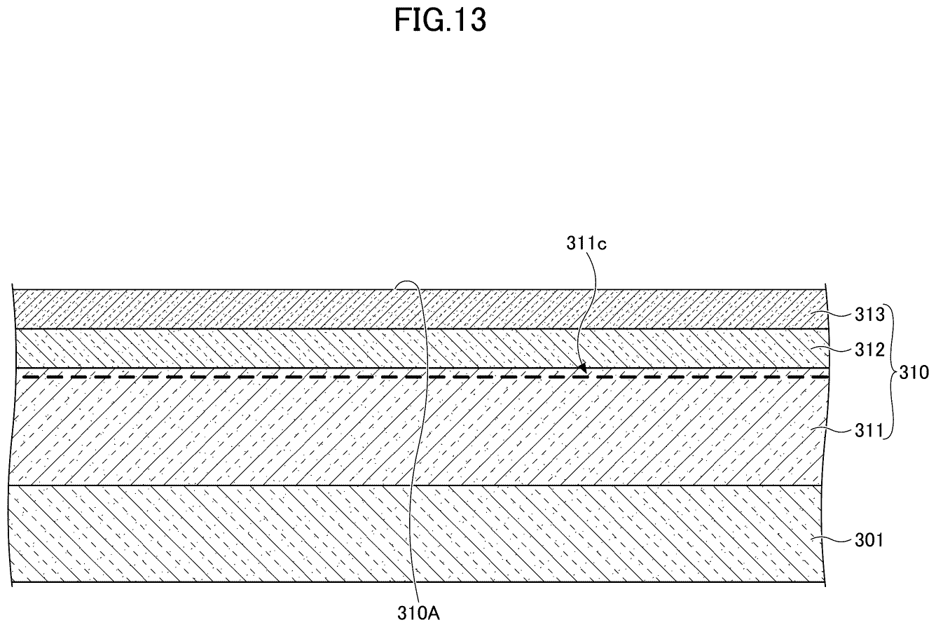

Next, the third embodiment will be described. The third embodiment relates to a production method for a semiconductor device including a GaN-based HEMT. FIGS. 13 to 24 are cross-sectional views illustrating the production method for the semiconductor device according to the third embodiment.

In the third embodiment, first, as illustrated in FIG. 13, a nitride semiconductor layer 310 containing Ga is formed on a substrate 301, for example, through MOCVD. In the formation of the nitride semiconductor layer 310, a channel layer 311, a barrier layer 312, and a cap layer 313 are formed sequentially. The nitride semiconductor layer 310 is an example of the first nitride semiconductor layer.

The substrate 301 is, for example, a substrate for growth of a GaN-based semiconductor. In one example, the substrate 301 is a SiC substrate that is semi-insulating. When the substrate 301 is the SiC substrate, the surface of the substrate 301 is a surface having Si polarity. When the surface of the substrate 301 is the surface having Si polarity, crystal growth of the channel layer 311, the barrier layer 312, and the cap layer 313 can be performed with the surface having Ga polarity being the growth surface.

The channel layer 311 is, for example, a GaN layer. The thickness of the channel layer 311 is, for example, 200 nm or greater and 2,000 nm or smaller. In one example, the thickness of the channel layer 311 may be 1,000 nm. A buffer layer may be formed between the channel layer 311 and the substrate 301.

The barrier layer 312 is, for example, an AlGaN layer. The band gap of the barrier layer 312 is greater than the band gap of the channel layer 311. The thickness of the barrier layer 312 is, for example, 5 nm or greater and 30 nm or smaller. In one example, the thickness of the barrier layer 312 may be 15 nm. When the barrier layer 312 is an AlₓGa₁₋ₓN layer, “x” for Al is, for example, 0.15 or greater and 0.35 or smaller. In one example, “x” for Al may be 0.25. Distortion occurs between the channel layer 311 and the barrier layer 312 due to the difference in lattice constants thereof, and this distortion induces piezoelectric charges at the interface between the channel layer 311 and the barrier layer 312. This generates 2 DEG near the interface between the channel layer 311 and the barrier layer 312, and forms a channel region 311c. Instead of the AlGaN layer, an InAlN layer or an InAlGaN layer may be used. Also, a spacer layer may be formed between the channel layer 311 and the barrier layer 312. The thickness of the spacer layer is, for example, 0.5 nm or greater and 3.0 nm or smaller. In one example, the thickness of the spacer layer may be 1.0 nm.

The cap layer 313 is, for example, a GaN layer. The thickness of the cap layer 313 is, for example, 1 nm b or greater and 5 nm or smaller. In one example, the thickness of the cap layer 313 may be 2 nm. The surface of the cap layer 313 forms the surface 310A of the nitride semiconductor layer 310.

On the surface having Si polarity of the SiC substrate, crystal growth of the channel layer 311, the barrier layer 312, and the cap layer 313 is performed with the surface having Ga polarity being the growth surface. Therefore, of the two main surfaces of the channel layer 311, the barrier layer 312, or the cap layer 313, the main surface the farthest from the substrate 301 (upper surface) becomes a surface having Ga polarity, and the main surface the closest to the substrate 301 (lower surface) becomes a surface having N polarity.

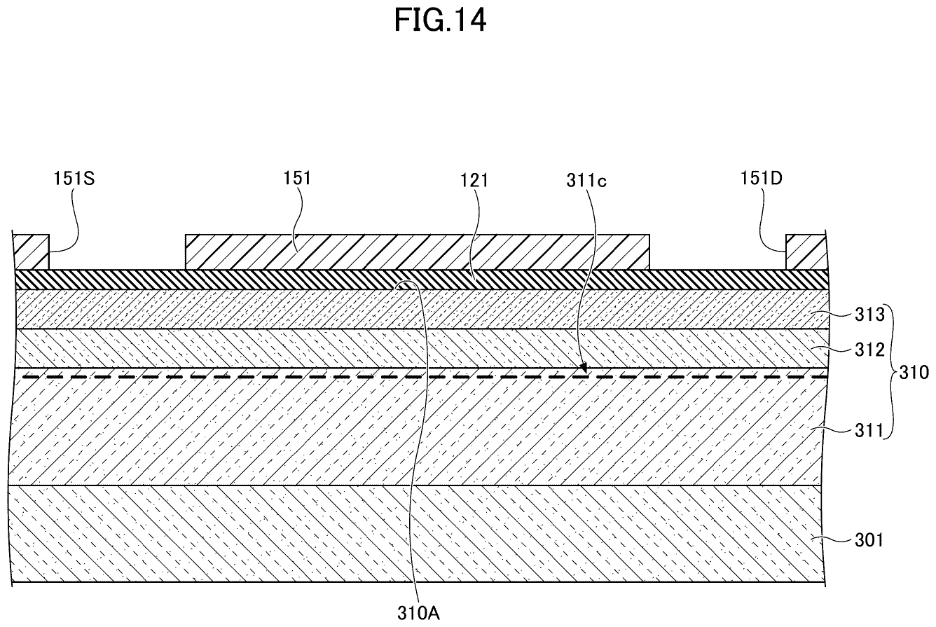

Next, as illustrated in FIG. 14, a SiN layer 121 contacting the surface 310A of the nitride semiconductor layer 310 is formed. Next, the resist pattern 151 is formed on the SiN layer 121. The resist pattern 151 has an opening 151S for a source and an opening 151D for a drain.

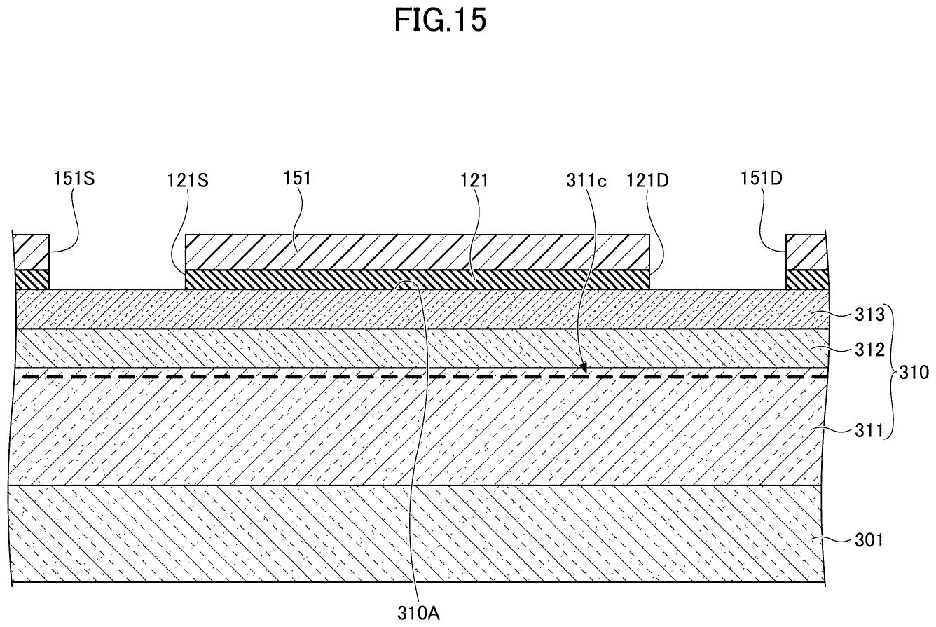

Next, as illustrated in FIG. 15, the SiN layer 121 is etched using the resist pattern 151 as a mask. This etching is, for example, RIE using fluorine-containing gas. As a result, the opening 121S is formed at the SiN layer 121 below the opening 151S, and the opening 121D is formed at the SiN layer 121 below the opening 151D. A part of the nitride semiconductor layer 310 is exposed from the opening 121S, and another part of the nitride semiconductor layer 310 is exposed from the opening 121D.

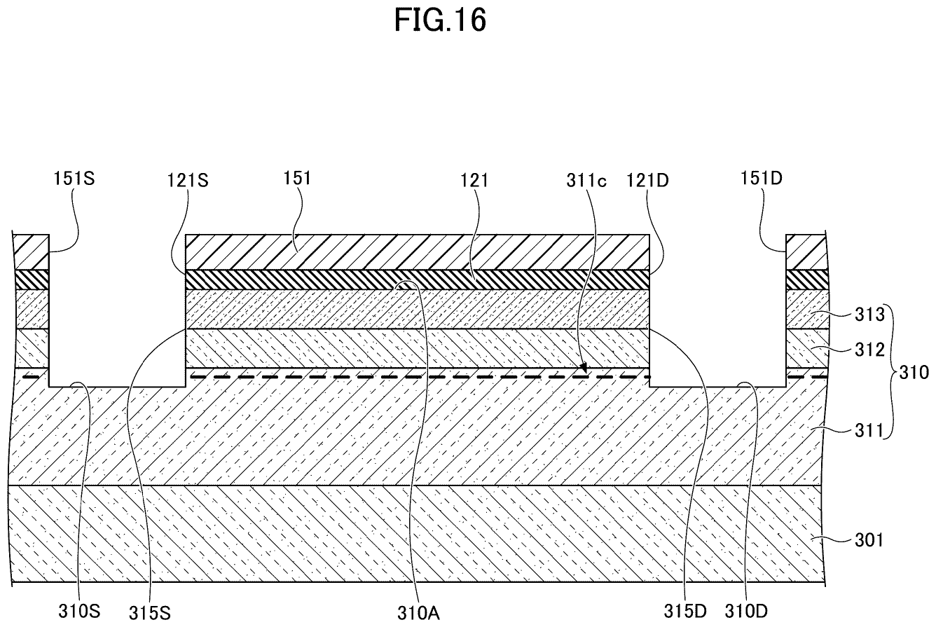

Next, as illustrated in FIG. 16, by etching the nitride semiconductor layer 310 using the resist pattern 151 as a mask, a recess 315S continuous with the opening 121S and a recess 315D continuous with the opening 121D are formed at the nitride semiconductor layer 310. This etching is, for example, RIE using chlorine-containing gas. For example, the recesses 315S and 315D are formed at a depth that penetrates the channel region 311c. That is, the recesses 315S and 315D are deeper than the channel region 311c, with the reference being the surface 310A of the nitride semiconductor layer 310. The formation of the recesses 315S and 315D may be stopped in the middle of the barrier layer 312. That is, the recesses 315S and 315D may be formed such that the bottom surfaces of the recesses 315S and 315D are positioned in the barrier layer 312.

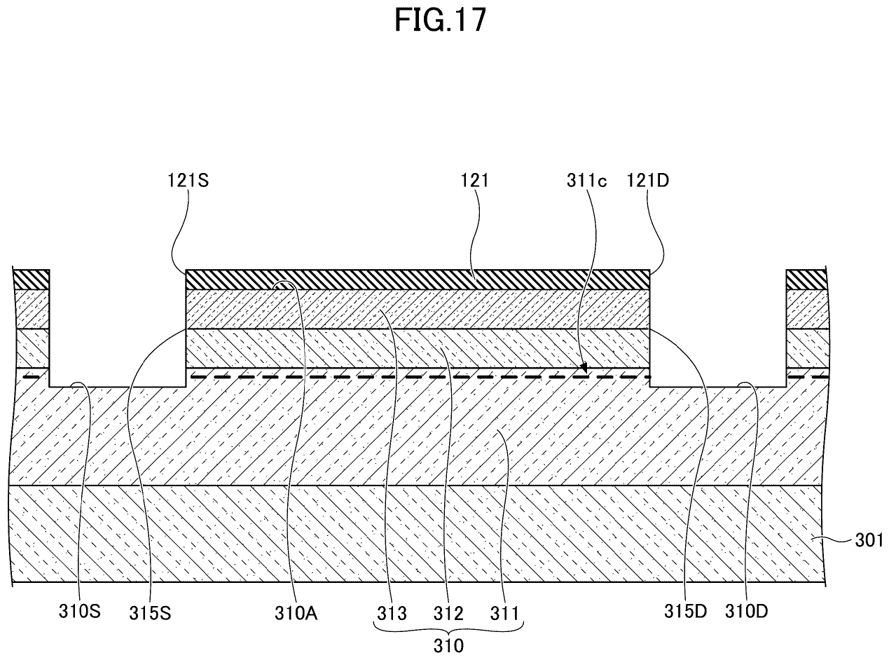

Next, as illustrated in FIG. 17, the resist pattern 151 is removed using a chemical solution. Next, a surface 310S, exposed from the opening 121S of the nitride semiconductor layer 310, and a surface 310D, exposed from the opening 121D of the nitride semiconductor layer 310, are subjected to the reduction treatment in a MOCVD chamber using the first gas mixture containing N₂, H₂, and NH₃. In this reduction treatment, for example, the temperature of the substrate 301 is set to be 700° C. or higher and 900° C. or lower, and may be set to be 750° C. or higher and 850° C. or lower. During the period of from the formation of the openings 121S and 121D until the removal of the resist pattern 151, a native oxide film can be formed on the surfaces 310S and 310D. However, the native oxide film is removed with this reduction treatment. For example, the surface 310S is an inner surface (bottom surface and side wall surface) of the recess 315S, and the surface 310D is an inner surface (bottom surface and side wall surface) of the recess 315D. The surfaces 310S and 310D are an example of the first surface.

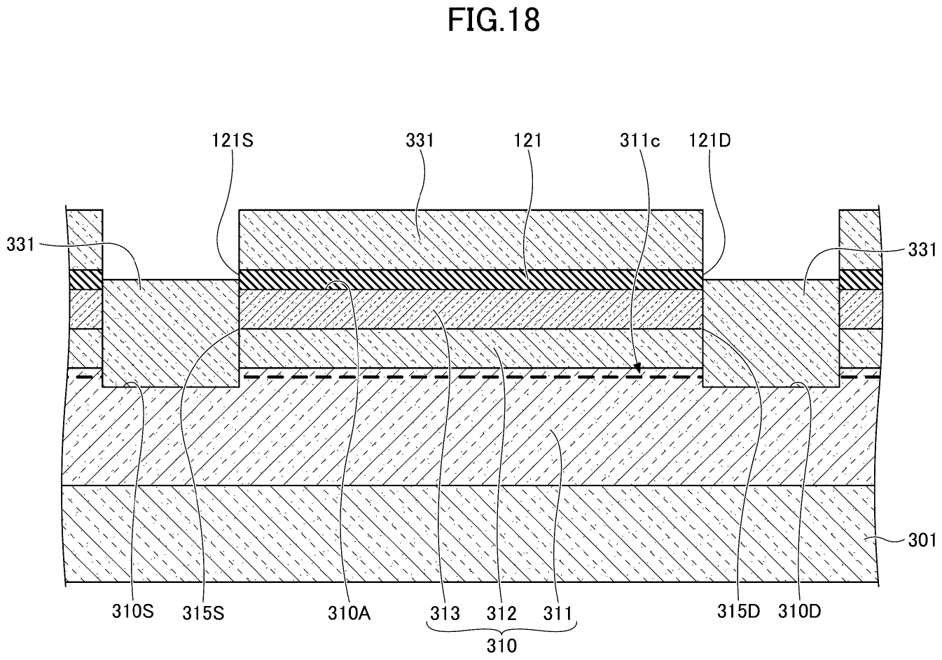

Next, as illustrated in FIG. 18, an n-type GaN layer 331 is formed to fill the recesses 315S and 315D. In the formation of the n-type GaN layer 331, the film formation is performed using the second gas mixture, containing N₂, H₂, NH₃, and a source material of gallium, in the same MOCVD chamber without exposing the MOCVD chamber to the atmosphere. For example, trimethylgallium (TMG) or TEG is used as the source material of gallium. The n-type GaN layer 331 is deposited not only on the nitride semiconductor layer 310 but also on the SiN layer 121. The n-type GaN layer 331 may also be formed in the openings 121S and 121D. On the surface having Ga polarity of the nitride semiconductor layer 310, crystal growth of the n-type GaN layer 331 is performed with the surface having N polarity being the growth surface. Therefore, of the two main surfaces of the n-type GaN layer 331 on the surface having Ga polarity of the nitride semiconductor layer 310, the main surface the farthest from the substrate 301 (upper surface) becomes a surface having Ga polarity, and the main surface the closest to the substrate 301 (lower surface) becomes a surface having N polarity.

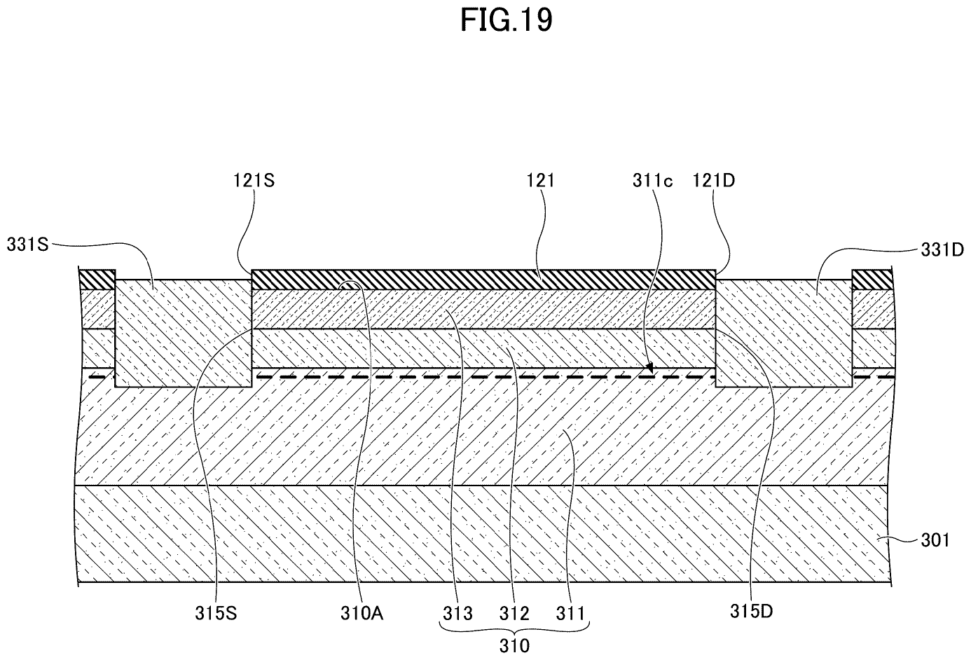

Next, as illustrated in FIG. 19, the n-type GaN layer 331 of the SiN layer 121 is removed using an alkaline solution, such as an aqueous sodium hydroxide solution. Because on the surface having Ga polarity of the nitride semiconductor layer 310, the upper surface of the n-type GaN layer 331 is a surface having Ga polarity, the n-type GaN layer 331 in the recess 315S and the n-type GaN layer 331 in the recess 315D are not etched. As a result, an n-type GaN layer 331S is formed in the b recess 315S, and an n-type GaN layer 331D is formed in the recess 315D. The n-type GaN layers 331S and 331D are an example of the second nitride semiconductor layer.

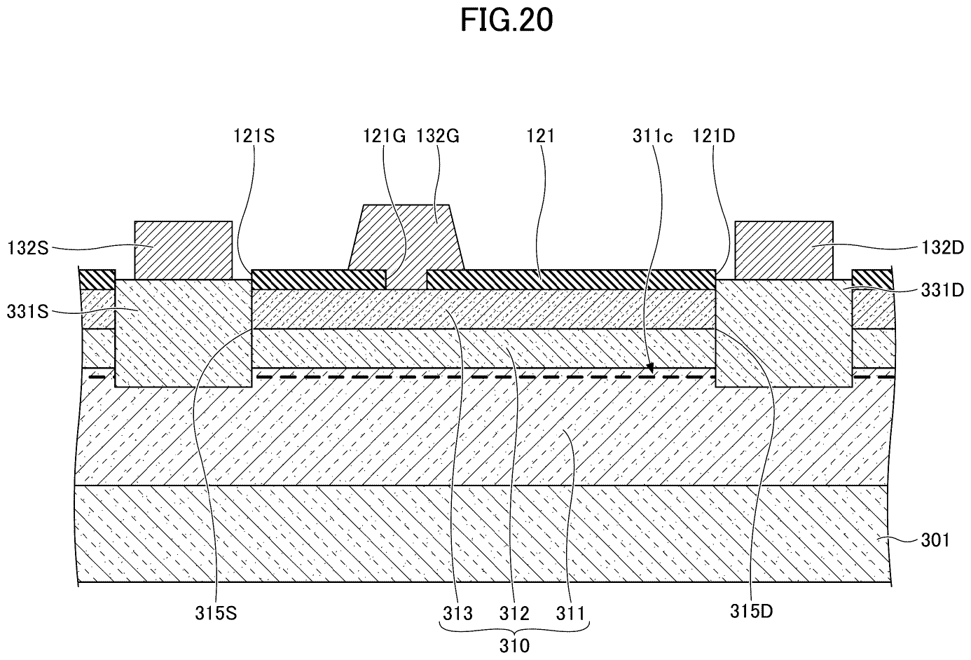

Next, as illustrated in FIG. 20, the source electrode 132S is formed on the n-type GaN layer 331S, and the drain electrode 132D is formed on the n-type GaN layer 331D. Next, the opening 121G is formed at the SiN layer 121 between the source electrode 132S and the drain electrode 132D. A part of the nitride semiconductor layer 310 is exposed from the opening 121G. Next, the gate electrode 132G contacting the nitride semiconductor layer 310 through the opening 121G is formed.

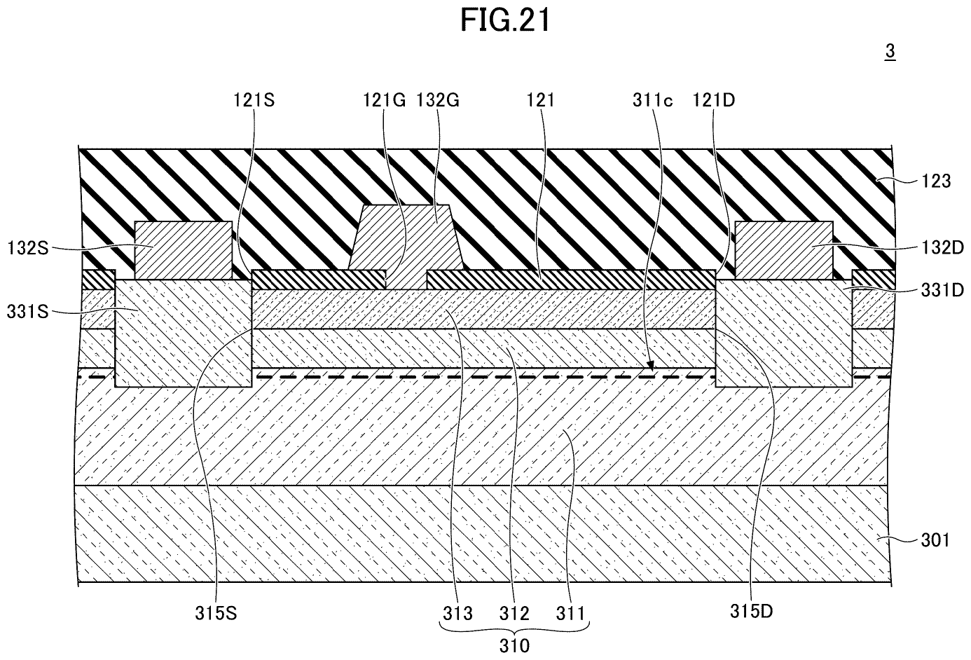

Next, as illustrated in FIG. 21, the SiN layer 123 is formed on the SiN layer 121. The SiN layer 123 covers the n-type GaN layer 331S, the source electrode 132S, the n-type GaN layer 331D, the drain electrode 132D, and the gate electrode 132G.

In this manner, a semiconductor device 3 can be produced.

In the third embodiment, the reduction treatment is performed in the MOCVD chamber in which the n-type GaN layer 331 is to be formed, and the n-type GaN layer 331 is formed in this MOCVD chamber. Therefore, the n-type GaN layer 331 is formed in a state in which the native oxide film is removed. Thus, the contact resistance between: the source electrode 132S and the drain electrode 132D; and the nitride semiconductor layer 310 can be reduced.

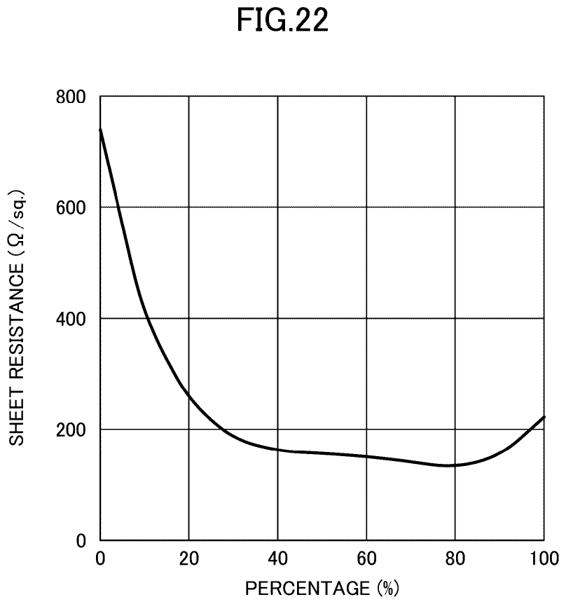

In the present disclosure, no limitation is imposed on the relative percentages of hydrogen and nitrogen in the second gas mixture. However, when a percentage R of the flow rate of nitrogen relative to the total flow rate of hydrogen and nitrogen is 30% or more b and 95% or less, the resulting second nitride semiconductor layer is likely to have low sheet resistance. When the percentage R is 60% or more and 90% or less, the second nitride semiconductor layer is likely to have further low sheet resistance. When the percentage R is 75% or more and 85% or less, the second nitride semiconductor layer is likely to have especially low sheet resistance. When the percentage R is less than 30%, the percentage of hydrogen is excessively high. As a result, the growth rate is excessively increased and the surface morphology is degraded, and the sheet resistance is likely to be high. Meanwhile, when the percentage R is higher than 95%, crystallinity of the second nitride semiconductor layer is lowered, and the sheet resistance can be high. FIG. 22 is a graph illustrating an example of a relationship between the second nitride semiconductor layer and the percentage R of the flow rate of nitrogen relative to the total flow rate of hydrogen and nitrogen in the second gas mixture.

Although embodiments have been described above in detail, the present disclosure is not limited to these specific embodiments, and various changes and modifications are possible within the scope of the claims recited.

What is claimed is:

1. A production method for a semiconductor device, the production method comprising:
forming a first nitride semiconductor layer containing gallium, on a substrate;
forming a mask layer on the first nitride semiconductor layer;
forming an opening in the mask layer, a part of the first nitride semiconductor layer being exposed from the opening;
performing a reduction treatment of a first surface of the first nitride semiconductor layer in a chamber using a first gas mixture containing hydrogen and ammonia, the first surface being exposed from the opening;
forming a second nitride semiconductor layer of a first conductive type on the first surface through metal organic chemical vapor deposition in the chamber using a second gas mixture containing hydrogen, nitrogen, ammonia, and a source material of a Group III element; and
forming an electrode on the second nitride semiconductor layer.

2. The production method for the semiconductor device according to claim 1, wherein
the mask layer is a silicon nitride layer.

3. The production method for the semiconductor device according to claim 1, wherein
the second nitride semiconductor layer is an n-type gallium nitride layer.

4. The production method for the semiconductor device according to claim 1, wherein
the first gas mixture contains nitrogen.

5. The production method for the semiconductor device according to claim 1, wherein
the first surface is a surface having N polarity.

6. The production method for the semiconductor device according to claim 5, wherein
the formation of the first nitride semiconductor layer includes
forming a barrier layer, and
forming a channel layer on the barrier layer.

7. The production method for the semiconductor device according to claim 6, further comprising:
forming a recess at a part of the channel layer between the formation of the opening and the reduction treatment, the part being exposed from the opening, wherein
the first surface is an inner surface of the recess.

8. The production method for the semiconductor device according to claim 1, wherein
the second gas mixture contains triethylgallium as the source material of the Group III element.

9. The production method for the semiconductor device according to claim 1, wherein
a percentage of a flow rate of nitrogen relative to a total flow rate of hydrogen and nitrogen in the second gas mixture is 30% or more and 95% or less.
